(19) United States
(12) Patent Application Publication
(10) Pub. No.: US 2009/0161335 A1
(43) Pub. Date: Jun. 25, 2009

(54) Housing of a Power Filter

(75) Inventors: Wangzhou Li, Dong-Guan City (CN); Hengtao Zhao, Dong-Guan City (CN); Heng Zhang, Dong-Guan City (CN); Jianwen Sun, Dong-Guan City (CN)

Correspondence Address: GROSSMAN, TUCKER, PERREAULT & PFLEGER, PLLC, 55 SOUTH COMMERICAL STREET, MANCHESTER, NH, 03101, US

(73) Assignee: DELTA ELECTRONICS, INC., Taoyuan Hsien (TW)

(21) Appl. No.: 12/112,403

(22) Filed: Apr. 30, 2008

(30) Foreign Application Priority Data
Dec. 21, 2007 (TW) 096221861

(51) Int. Cl. H05K 9/00; H02M 7/00

(52) U.S. Cl. 361/818; 327/531

(57) ABSTRACT

A housing adapted for a power filter and a power filter comprising the housing are provided. The power filter further comprises a filter element, a protection ring, and a connection line. The housing comprises a bottom wall, a sidewall, and an opening. The sidewall is disposed adjacent to the bottom wall to define a receiving space for receiving the filter element. The sidewall comprises an upper edge, with the opening extending downwards from the upper edge. The protection ring for protecting the connection line can be inserted into and fixed in the opening from the upper edge. With this opening, the power filter of the present invention can be assembled with greater ease.

This application claims priority to Taiwan Patent Application No. 096221861 filed on Dec. 21, 2007, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to a housing adapted for use in a power filter, and more particularly, the present invention relates to a housing that allows a more convenient assembly of a power filter.

2. Descriptions of the Related Art

Over recent years, with the thriving development of hi-tech industries, various electronic products such as computers have been widely used. Typically, an electronic product incorporates a lot of electronic components, and almost all of these electronic components contribute to a high electromagnetic interference (EMI), especially the power supply of the product. A high EMI not only interferes with the operation of the electronic components, but may also cause serious interference with the circuits within the electronic product and even cause damage or failure to the electronic product. Furthermore, serious EMI interference from an electronic product may also cause abnormal operations or damage to other electronic products. Therefore, electronic products are generally equipped with a power filter to mitigate the EMI interference with the electronic products.

As shown in FIG. 1, a typical power filter 1 comprises a housing 2, a plurality of filter elements 11, four connection lines 13, and four corresponding protection rings 15. FIG. 2 illustrates the perspective view of the housing 2. The housing 2 has a bottom wall 21 and four sidewalls 23, 25, which together define a receiving space 20 for receiving the filter elements 11. Each of the two opposite sidewalls 23 of the housing 2 is formed with a pair of round openings 22, through which the connection lines 13 connect the filter elements 11. Here, the filter elements 11 include capacitors and inductors.

In the prior art, the housing 2 is made of metal so the side surfaces of the round openings 22 are rigid and sharp edges. On the other hand, the outer sheaths of the connection lines 13 are insulation layers made of polyvinyl chloride (PVC). To prevent the PVC insulation layers of the connection lines, which are inserted through the round openings 22, from being damaged by the metal housing 2 and losing its insulating function, one protection ring 15 made of rubber has to be disposed in each of the round openings 22. However, this process demands a sophisticated installation staff to dispose the protection rings 15 into the round openings 22 properly and quickly. Moreover, when installing the connection lines 13, the installation staff has to assemble the filter elements 11 outside the housing 2, place the filter elements 11 into the housing 2 of the power filter 1, insert the connection lines 13 through the round openings 22, arrange the connection lines 13 in the housing 2 and then solder the connection lines 13 to the filter elements 11. This process is very labor-intensive. Furthermore, due to the restrictions of the receiving space 20, the connection lines 13 are difficult to solder to the filter elements 11 within the housing 20. Sometimes, some of the solder beads may fall into the receiving space 20, potentially causing trouble in the power filter 1.

Thus, the poor structural design of the conventional power filter housings makes it difficult to assemble the power filters, and makes it easy for the solder beads to fall into the housings when the connection lines are being soldered to the filter elements, thus causing the degradation of the yield and safety level. Accordingly, it is highly desired in the field to provide an improved housing structure for a power filter to facilitate the assembly of the power filter.

### SUMMARY OF THE INVENTION

One objective of this invention is to overcome the aforesaid drawbacks of the conventional power filter housings by providing a power filter housing that allows easy assembly to achieve a higher yield and safety level of a power filter incorporating such a housing.

This invention provides a housing adapted for a power filter. The power filter has a filter element, while the housing comprises a bottom wall, at least one sidewall and at least one opening. The at least one sidewall has an upper edge, and is disposed adjacent to the bottom wall to define a receiving space for receiving the filter element. The at least one opening extends downward from the upper edge.

Another objective of this invention is to provide a power filter, which comprises an aforesaid housing, a filter element, at least one protection ring and at least one connection line. The protection ring has an outer annular surface and a groove formed annularly on the outer annular surface. The connection line is connected with the filter element by being partially inserted through the protection ring. Thereby, the protection ring is inserted from the top into the bottom portion of the opening to be fixed in the opening of the aforesaid housing.

With this arrangement, the connection line may be connected to the filter element outside the housing and pre-inserted through the protection ring. Afterwards, the protection ring assembled with the filter element and the connection line are inserted into the opening from the top.

Such an installation process remarkably eases the difficulties encountered in installing the protection rings and connecting the connection lines and filter elements in conventional housings, and to prevent solder beads from falling into the housing. As a result, this may save on labor, increase production yield and improve the safety level.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 is a perspective view of a conventional power filter;

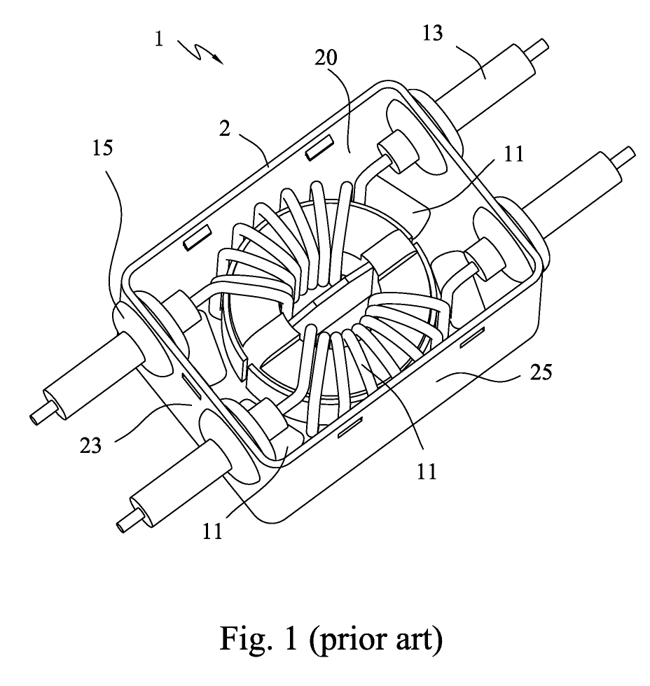

FIG. 2 is a perspective view of a housing adapted for the power filter shown in FIG. 1;

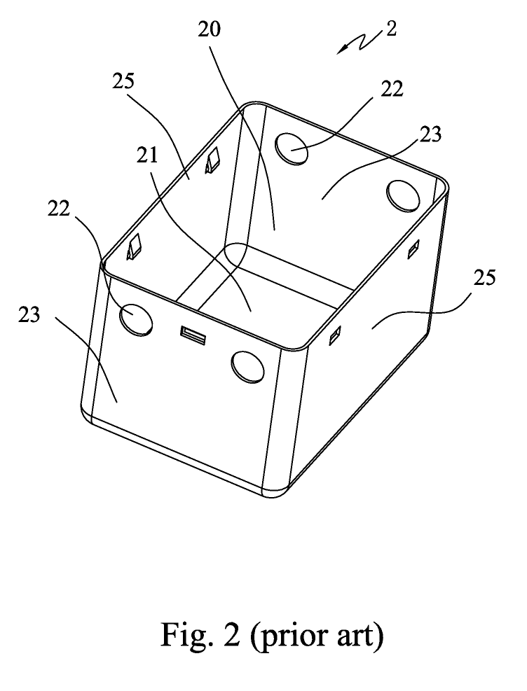

FIG. 3 is a perspective view of a power filter in accordance with an embodiment of this invention;

FIG. 4A is a perspective view of a housing adapted for the power filter shown in FIG. 3; and

FIG. 4B is a side view of the housing adapted for the power filter shown in FIG. 3.

### DESCRIPTION OF THE PREFERRED EMBODIMENT

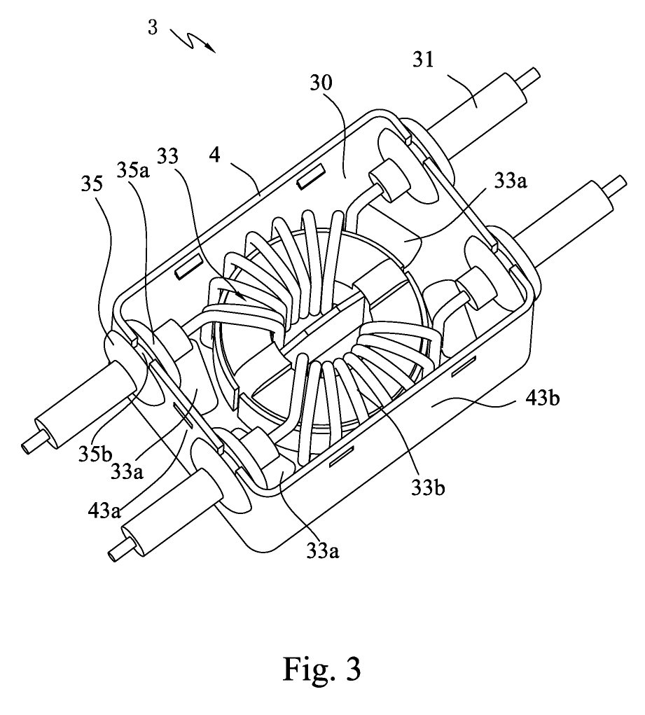

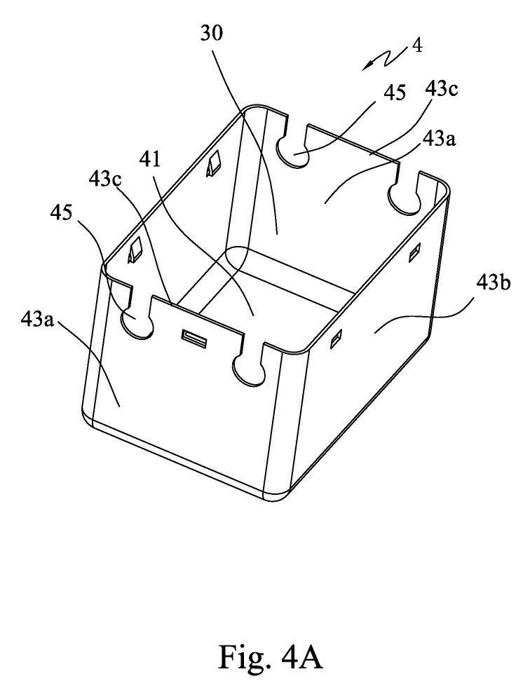

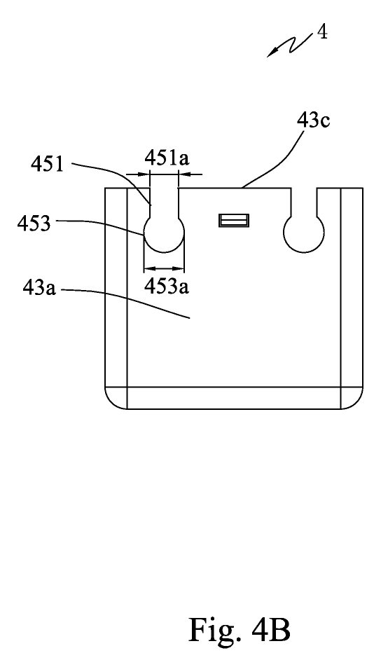

An embodiment of this invention is a power filter 3, the perspective view of which is depicted in FIG. 3. The power filter 3 comprises a housing 4, four connection lines 31, a plurality of filter elements 33 and four protection rings 35. FIG. 4A and FIG. 4B illustrate the perspective view and the side view of the housing 4 respectively.

The housing 4 comprises a bottom wall 41, four sidewalls 43a, 43b, and four openings 45. Since the bottom wall 41 has a rectangular profile and the four sidewalls 43a, 43b are disposed adjacent to the rectangular bottom wall 41 in this embodiment, the four sidewalls 43a, 43b and the bottom wall 41 jointly define a rectangular receiving space 30 for receiving the filter elements 33 of the power filter 3.

Each of the sidewalls 43a, 43b has an upper edge 43c, and each of the two opposite sidewalls 43a are formed respectively with the two openings 45 extending downwards from the upper edge 43c. Each of the openings 45 has an upper portion 451 and a lower portion 453, with a first width 451a of the upper portion 451 less than a second width 453a of the lower portion 453. In other embodiments, the first width 451a of the upper portion 451 may also be equal to the second width 453a of the lower portion 453. In this embodiment, the housing 4 is made of metal. However, in other embodiments, the housing 4 may also be made of other appropriate materials instead.

The filter elements 33 comprise a number of inductors 33a and a number of capacitors 33b. In other embodiments, the filter elements 33 may further comprise other electronic components to enhance the filtering function or other functions.

The protection rings 35 each have an outer annular surface 35a and a groove 35b formed annularly on the outer annular surface 35a. The protection rings 35 are adapted for insertion through the openings 45 with the grooves 35b. In this embodiment, the protection rings 35 are made of rubber. The connection lines 31 are led through respective protection rings 35 to connect with the filter elements 33 disposed inside the housing 4, and are partially inserted through respective protection rings 35.

During assembly of the power filter 3, the four connection lines 31 may be connected with the filter elements 33 outside the housing 4, and be partially inserted through the four protection rings 35 respectively. Subsequently, the protection rings 35, together with the connection lines 31 and the filter elements 33, are inserted into the upper portions 451 of the openings 45 from the upper edges 43c of the sidewalls 43a and fixed to the lower portions 453 of the openings 45 in the grooves 35b of the protection rings 35, thus completing the assembly of the power filter 3.

The materials of the individual components of this invention are not merely limited to those mentioned in this embodiment. For instance, the material of the housing is not merely limited to metal, but may also be polymer, wood, or even ceramic material. Likewise, the material of the protection ring is not limited to rubber, but may also be made of other elastic polymers. Furthermore, the arrangement of the various elements in this invention is also not merely limited to what is described in this embodiment. For instance, the housing does not need to only have two opposite sidewalls, and the openings are not limited to the two pairs of opposite openings arranged on the two opposite sidewalls. Instead, depending on the practical requirements, more than one opening can be arranged on the other sidewalls.

With the aforesaid simple installation process, this invention makes it easier to install the protection rings and to solder the connection lines and filter elements in the conventional housings. Furthermore, solder beads are prevented from falling into the receiving space of the housing. As a result, this may save labor costs, increase production yield of the power filter and improve the safety level.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A housing adapted for use in a power filter, the power filter having a filter element, the housing comprising:
a bottom wall;
at least one sidewall, having an upper edge, wherein the at least one sidewall is disposed adjacent to the bottom wall to define a receiving space for receiving the filter element; and
at least one opening, extending downward from the upper edge, having an upper portion and a lower portion, wherein the upper portion has a first width and the lower portion has a second width which is greater than the first width.

2. The housing as claimed in claim 1, wherein the at least one sidewall comprises two opposite sidewalls, and the at least one opening comprises a pair of openings disposed at the upper edges of the two opposite sidewalls, respectively.

3. The housing as claimed in claim 1, wherein the at least one sidewall comprises two opposite sidewalls, and the at least one opening comprises two pairs of openings disposed at the upper edges of the two opposite sidewalls, respectively.

4. The housing as claimed in claim 1, wherein the housing is made of metal.

5. A power filter, comprising:
one housing as claimed in claim 1;
a filter element;
at least one protection ring, having an outer annular surface and a groove formed annularly on the outer annular surface, adapted to be inserted through the at least one opening with the groove; and
at least one connection line connected with the filter element and partially passing through the at least one protection ring.

6. The power filter as claimed in claim 5, wherein the at least one sidewall comprises two opposite sidewalls, and the at least one opening comprises a pair of openings disposed at the upper edges of the two opposite sidewalls, respectively.

7. The power filter as claimed in claim 5, wherein the at least one sidewall comprises two opposite sidewalls, and the at least one opening comprises two pairs of openings disposed at the upper edges of the two opposite sidewalls, respectively.

8. The power filter as claimed in claim 7, wherein the at least one connection line comprises four connection lines, the at least one protection ring comprises four protection rings, the connection lines partially passes through these protection rings, and the protection rings are adapted to be inserted into the two pairs of openings, respectively.

9. The power filter as claimed in claim 5, wherein the at least one protection ring is made of rubber.

10. The power filter as claimed in claim 5, wherein the filter element comprises an inductor and a capacitor.

11. The power filter as claimed in claim 5, wherein the housing is made of metal.
